(19) United States
(12) Patent Application Publication
(10) Pub. No.: US 2005/0230695 A1
(43) Pub. Date: Oct. 20, 2005

(54) Semiconductor light-emitting element and method for manufacturing the same

(75) Inventor: Toru Takayama, Nara-shi (JP)

Correspondence Address: HAMRE, SCHUMANN, MUELLER & LARSON P.C., P.O. BOX 2902, MINNEAPOLIS, MN, 55402, US

(73) Assignee: Matsushita Electric Industrial Co., Ltd., Kadoma-shi (JP)

(21) Appl. No.: 11/077,831

(22) Filed: Mar. 11, 2005

(30) Foreign Application Priority Data
Apr. 6, 2004 (JP) 2004-112338

(51) Int. Cl. H01L 29/22

(52) U.S. Cl. 257/94

(57) ABSTRACT

A semiconductor light-emitting element includes a first conductivity-type cladding layer made of an In_{1-x-y}GaₓAl_{y}N (0≦x, y≦1) type material; a quantum well active layer including a barrier layer made of an In_{1-x-y}GaₓAl_{y}N (0≦x, y≦1) type material and a well layer made of In₁₋ₓGaₓN (0≦x≦1) material; and a second conductivity type cladding layer made of an In_{1-x-y}GaₓAl_{y}N (0≦x, y≦1) type material. The mole fractions of the constituent components of the layers are selected such that (x+1.2y) is in a range of 1±0.1, suppressing phase separation to a minimum. Thus, a light-emitting element is provided in which an increase of leakage currents in the GaN semiconductor light-emitting element using an MQW active layer made of ternary InGaN is prevented, which is capable of high output operation, and which has long-term reliability.

### FIELD OF THE INVENTION

The present invention relates to structures and processes for semiconductor light-emitting elements, and especially to semiconductor light-emitting elements whose principal component is a Group III nitride material used in laser diodes as well as methods for manufacturing the same.

### BACKGROUND OF THE INVENTION

Blue laser light sources are an essential technology for next generation high density optical devices such as disk storage devices and DVDs. FIG. 11 shows a cross-sectional view of a conventional semiconductor laser device (S. Nakamura, MRS Bulletin Vol. 23 No. 5 pp. 37-43, 1998). A gallium nitride (referred to below as GaN) buffer layer 10 and an n-type GaN layer 15 are formed on a sapphire substrate 5 in this order. A pattern made of a silicon dioxide (SiO₂) layer 20 with a thickness of 0.1 μm further is formed, and stripe-shaped windows 25 with a width of 4 μm, at a period of 12 μm in the <1-100> direction of the GaN crystal further are formed. An n-type GaN layer 30, an n-type indium gallium nitride (In_{0.1}Ga_{0.9}N) layer 35, an n-type aluminum gallium nitride ((Al_{0.14}Ga_{0.86}N)/GaN) modulation doped strained layer superlattice (referred to below as MD-SLS) cladding layer 40, and an n-type GaN cladding layer 45 are formed in that order on top thereof. Furthermore, a (In_{0.022}Ga_{0.98}N/In_{0.15}Ga_{0.85}N) multiple quantum well (referred to below as MQW) active layer 50 is formed, and a p-type Al_{0.2}Ga_{0.8}N cladding layer 55, a p-type GaN cladding layer 60, a p-type Al_{0.14}Ga_{0.86}N/GaN MD-SLS cladding layer 65, and a p-type GaN cladding layer 70 are formed on top thereof.

The p-type MD-SLS cladding layer 65 is formed in a ridge stripe structure and is configured to confine a light distribution propagating within the ridge waveguide structure in the horizontal, longitudinal direction. Electrodes (not shown) are formed on the p-type GaN cladding layer 70 and the n-type GaN cladding layer 30 to inject current.

In the structure shown in FIG. 11, the n-type GaN cladding layer 45 and the p-type GaN cladding layer 60 are optical waveguide layers. The n-type MD-SLS cladding layer 40 and the p-type MD-SLS cladding layer 65 act as the cladding layers that confine carriers and light injected into the active region of the MQW layer 50. The n-type In_{0.1}Ga_{0.9}N layer 35 acts as a buffer layer that prevents the occurrence of cracks when a thick AlGaN film is grown.

In the semiconductor laser of the structure shown in FIG. 11, the carriers are injected into the MQW active layer 50 through the electrode, and light in the wavelength band of 400 nm is emitted. The effective refractive index is lower in the ridge stripe region than outside thereof, making it possible to confine the light distribution in the horizontal lateral direction within the active layer by the formed ridge waveguide structure in the p-type MD-SLS cladding layer 65.

On the other hand, the refractive index of the active layer is larger than the refractive index of the n-type GaN cladding layer 45 and the p-type GaN cladding layer 60, and the refractive index of the n-type MD-SLS cladding layer 40 and the p-type MD-SLS cladding layer 60, making it possible to confine the light distribution in the vertical direction within the active layer by the n-type GaN cladding layer 45, the n-type MD-SLS cladding layer 40, the p-type GaN cladding layer 60, and the p-type MD-SLS cladding layer 55, and in cooperation with the above-described effect, a fundamental transverse-mode oscillation is obtained.

However, in the case of the structure shown in FIG. 11, because the lattice constants of AlGaN, InGaN, and GaN are different from one another, when the entire thickness of the n-type In_{0.1}Ga_{0.9}N layer 35, the (In_{0.02}Ga_{0.98}N/In_{0.15}Ga_{0.85}N) MQW active layer 50, the n-type (Al_{0.14}Ga_{0.86}N/GaN) MD-SLS cladding layer 40, the p-type (Al_{0.14}Ga_{0.86}N/GaN) MD-SLS cladding layer 65, and the p-type Al_{0.2}Ga_{0.8}N cladding layer 55 exceeds a critical thickness, lattice defects occur by which the distortion energy is released consistently. Because the lattice defects act as absorption centers of laser light, the light emission efficiency decreases, and the threshold current rises. This effect is particularly prominent when the lattice defect density is at least 10⁸/cm³.

However, above the above-mentioned critical thickness, it is difficult to decrease the defect density to an order of magnitude smaller than 10⁸/cm³, making it difficult to realize a laser that assures the long term reliability of at least 10000 hours.

Especially, if the MQW active layer made of well layers and barrier layers is configured entirely with InGaN material, because the lattice constant of the active layer is different from that of GaN, the active layer itself, which serves as the light-emitting layer, may exceed the critical film thickness, and lattice defects may occur within the active layer, so that deterioration of the reliability in that case is even more severe.

Furthermore, in order to realize a high temperature and high output semiconductor laser, it is necessary to make the band gap difference of the well layers and the barrier layers as large as possible and to prevent the carriers, once they have been injected into the well layers, from leaking to the outside of the wells by thermal energy before the carriers have recombined by simulated emission.

Furthermore, in consideration of the nitride mixed crystal semiconductor constituted by InN, AlN, and GaN, the lattice mismatches between InN and GaN, between InN and AlN, and between GaN and AlN are 11.3%, 13.9%, and 2.3% respectively. In this case, since the interatomic distances differ from one another among InN, GaN, and AlN, even if the composition were set so that the lattice constant of an InGaAlN layer is the same as that of GaN, for example, since the size of the interatomic spacing and the bond angle among the atoms constituting the InGaAlN layer is different from the size of the ideal state in the case of binary compound semiconductor, an internal strain energy accumulates within the InGaAlN layer.

In order to reduce the internal strain energy, there is a range of compositions over which phase separation occurs in the InGaAlN material. If phase separation occurs, then In atoms, Ga atoms, and Al atoms are distributed unevenly within the InGaAlN layer and the atoms are not distributed evenly according to the mole fraction of the atoms in the constituting layers. This means that the band gap energy distribution and the refractive index distribution of the layers in which the phase separation occurred also become uneven. As a result of the phase separation, the region where the uneven composition is formed either acts as a light absorption center or scatters the guided wave. Thus, if phase separation occurs, then the driving current of semiconductor lasers rises, thereby reducing the life of the semiconductor lasers.

Due to the above-described reasons, since material-related problems such as lattice defects and phase separation are likely to occur in nitride semiconductor lasers, if the MQW active layer made of conventional ternary InGaN is used, then leakage current increases. As a result, it is difficult to obtain semiconductor lasers operable at a high output of at least 100 mW and having long-term reliability.

### SUMMARY OF THE INVENTION

A semiconductor light-emitting element in accordance with the present invention comprises a first cladding layer of a first conductivity type made of an In_{1-x-y}GaₓAl_{y}N (0≦x, y≦1) type material; a quantum well active layer including a barrier layer made of an In_{1-x-y}GaₓAl_{y}N (0≦x, y≦1) type material and a well layer made of In₁₋ₓGaₓN (0≦x≦1) material; and a second cladding layer of a second conductivity type made of an In_{1-x-y}GaₓAl_{y}N (0≦x, y≦1) type material; wherein the mole fractions of the constituent components of the layers are selected such that (x+1.2y) is in a range of 1±0.1, suppressing phase separation to a minimum.

In a method for manufacturing a semiconductor light-emitting element in accordance with the present invention comprising a first cladding layer of a first conductivity type made of an In_{1-x-y}GaₓAl_{y}N (0≦x, y≦1) type material; a quantum well active layer including a barrier layer made of an In_{1-x-y}GaₓAl_{y}N (0≦x, y≦1) type material and a well layer made of In₁₋ₓGaₓN (0≦x≦1) material; and a second cladding layer of a second conductivity type made of an In_{1-x-y}GaₓAl_{y}N (0≦x, y≦1) type material, the layers are fabricated at a crystal growth temperature of at least 500° C. and at most 1100° C., and the mole fractions of the constituent components of the layers are selected such that (x+1.2y) is in a range of 1±0.1, suppressing phase separation to a minimum.

### BRIEF DESCRIPTION OF THE DRAWINGS

FIG. 1A shows a cross-sectional structural view of a semiconductor laser according to a first embodiment of the present invention. FIG. 1B is an enlarged cross-sectional view of the multiple quantum well active layer.

FIG. 2 is a graph showing the light-current characteristics of the semiconductor laser according to the first embodiment of the present invention.

FIGS. 3A to 3D are diagrams showing an outline of the steps for manufacturing the semiconductor laser according to the first embodiment of the present invention.

FIG. 4 shows a cross-sectional structural view of a semiconductor laser according to a second embodiment of the present invention.

FIG. 5 is a graph showing the light-current characteristics of the semiconductor laser according to the second embodiment of the present invention.

FIGS. 6A to 6C are diagrams showing an outline of steps for manufacturing the semiconductor laser according to the second embodiment of the present invention.

FIGS. 7A and 7B are diagrams showing an outline of steps for manufacturing the semiconductor laser according to the second embodiment of the present invention.

FIG. 8 is a graph showing the change of the phase separation regions for the constituent components of InGaAlN type material for various growth temperatures in the second Embodiment of the present invention.

FIG. 9 corresponds to the graph of FIG. 8, further marking a composition selection region for the Ga composition and the Al composition in the InGaAlN type material for preventing phase separation.

FIG. 10 corresponds to the graph of FIG. 8, further marking a composition selection region for the Ga composition and the Al composition in the InGaAlN type material for preventing phase separation and lattice matching with GaN.

FIG. 11 shows a cross-sectional structural view of a conventional semiconductor laser.

### DESCRIPTION OF THE PREFERRED EMBODIMENTS

According to the semiconductor light-emitting element of the present invention, it is possible to suppress the occurrence of lattice defects due to lattice mismatch with the substrate by letting the lattices of the atomic composition of the cladding layer and the barrier layer, which are made of InGaAlN material, match the lattice of the substrate.

Further, if the atomic composition of the layers constituting the semiconductor laser is formed within a range of atomic composition in which phase separation does not occur, then it is possible to suppress the occurrence of compositional separation and increase of waveguide loss.

Furthermore, if the barrier layer is formed with InGaAlN material including Al, then the band gap can be made larger than that of a barrier layer constituted by InGaN material, making it possible to reduce the leakage current. Furthermore, since it is easier to control the atomic composition ratio by using ternary InGaN as the well layer than using InGaAlN constituted by quaternary material, it becomes easier to control the emission wavelength, making it possible to obtain a high reproducibility of the desired emission wavelength.

As a result, it is possible to enhance the light emission efficiency significantly and obtain a nitride semiconductor laser that operates in the blue to green region and is suited for high output operation.

Furthermore, by adjusting the crystal growth temperature and the mole fraction of the components constituting the layers, it is possible to obtain a high-quality InGaAlN material in which phase separation does not occur.

In accordance with the present invention, in the first cladding layer, the barrier layer, the well layer, and the second cladding layer of the present invention, (x+1.2y) is selected to be within a range of 1±0.1. In this manner, by adjusting the mole fraction of Ga and the mole fraction of Al to a specific ratio, it is possible to make the lattice constants of the layers constituting the semiconductor laser substantially constant and to suppress the occurrence of lattice defects. In particular, by specifying the ratio, it is possible to make the lattice constants of the layers constituting the semiconductor laser substantially the same as the lattice constant of GaN, so that lattice defects can be reduced when forming the semiconductor laser on a GaN layer. If (x+1.2y) is less than 0.9, then the lattice constant of the In_{1-x-y}GaₓAl_{y}N layer becomes more than 1% larger than that of GaN, which is problematic in that a large compressive strain occurs in the In_{1-x-y}GaₓAl_{y}N layer, making it easier for the lattice defect to occur in the In_{1-x-y}GaₓAl_{y}N layer. If (x+1.2y) is greater than 1.1, then the lattice constant of the InGaAlN becomes more than 1% smaller than the lattice constant of GaN, which is problematic in that a large tensile strain occurs in the In_{1-x-y}GaₓAl_{y}N layer, so that lattice defects tend to occur in the In_{1-x-y}GaₓAl_{y}N layer.

When (x+1.2y) is within the range of 1±0.1 in the first cladding layer, the barrier layer, the well layer, and the second cladding layer, the difference between the lattice constant of each of these layers and the lattice constant (31.7 nm) of GaN of the substrate is at least −0.74 nm and at most +0.36 nm. This corresponds to a lattice mismatch with the GaN substrate of at least −2.33% and at most +1.13%. Therefore, in the present invention, it is preferable that the lattice mismatch of each of the first cladding layer, the barrier layer, the well layer, and the second cladding layer with the GaN as a material of the substrate is at least −2.33% and at most +1.13%.

Furthermore, it is preferable that the relationships O<x+y≦1 and 1≦x/0.8+y/0.89 hold true. It is also preferable that the crystal growth temperature is within a range from approximately 500° C. to approximately 1000° C. It is preferable that the second cladding layer at least has a ridge structure. It is thus possible to obtain a fundamental transverse-mode oscillation in which the light distribution propagating through the waveguide is stable.

Furthermore, the cladding layers can keep the compositional separation to a minimum, reduce the waveguide loss, and obtain a waveguide that confines the carriers injected into the active layer serving as the light-emitting portion and in which the light density at the active layer is maximal.

### Embodiment 1

Structure of Semiconductor Light-Emitting Element

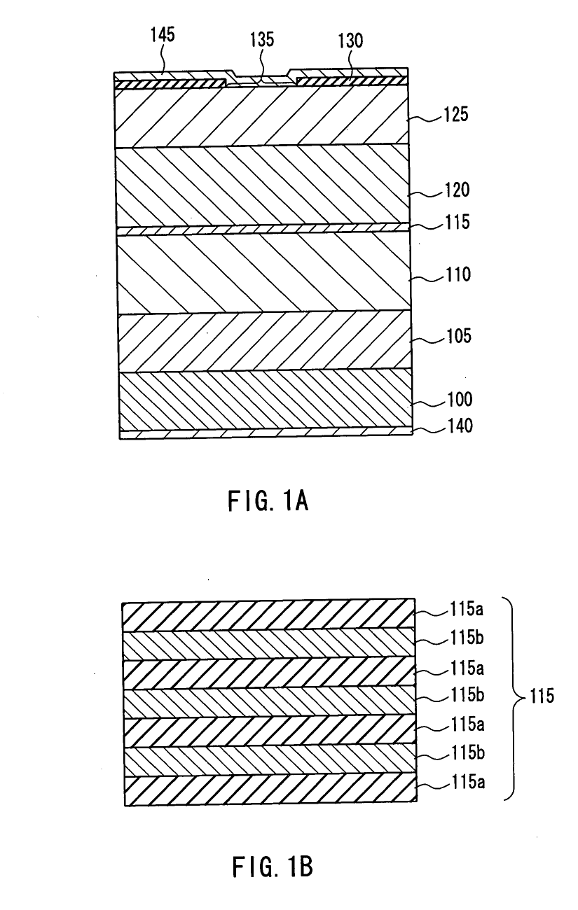

FIG. 1A and FIG. 1B show a cross-sectional view of a semiconductor light-emitting element according to a first embodiment of the present invention. As shown in FIG. 1A and FIG. 1B, an n-type GaN first cladding layer 105 (of approximately 0.5 μm thickness), an n-type In_{0.05}Ga_{0.75}Al_{0.2}N second cladding layer 110 (of approximately 1.5 μm thickness), and a multiple quantum well active layer 115 constituted by four barrier layers (each 3.5 nm thick) 115a made of In_{0.02}Ga_{0.85}Al_{0.13}N and three quantum well layers (each 3.5 nm thick) 115b made of In_{0.12}Ga_{0.88}N sandwiched therein are formed on top of an n-type GaN substrate 100.

Furthermore, a p-type In_{0.05}Ga_{0.75}Al_{0.2}N third cladding layer 120 (of approximately 1.5 μm thickness) and a p-type GaN fourth cladding layer 125 (of approximately 0.5 μm thickness) are formed thereon.

The first cladding layer 105 and the second cladding layer 110 of the present embodiment are n-type and correspond to the first cladding layer of a first conductivity type in the present invention. Furthermore, the third cladding layer 120 and the fourth cladding layer 125 of the present embodiment are p-type and correspond to the second cladding layer of a second conductivity type in the present invention.

As shown in FIG. 1B, the multiple quantum well active layer 115 of the present embodiment is formed in the order of In_{0.02}Ga_{0.85}Al_{0.13}N/In_{0.12}Ga_{0.88}N/In_{0.02}Ga_{0.85}Al_{0.13}N/In_{0.12}Ga_{0.08}N/In_{0.02}Ga_{0.85}Al_{0.13}N/In_{0.12}Ga_{0.88}N/In_{0.02}Ga_{0.85}Al_{0.13}N, with the thickness of each layer being 3.5 nm. That is, the multiple quantum well active layer 115 is constituted by the four barrier layers In_{0.02}Ga_{0.85}Al_{0.13}N (each 3.5 nm thickness) 115a and the three quantum well layers (each 3.5 nm thickness) 115b made of In_{0.12}Ga_{0.88}N sandwiched therein.

A SiO₂ layer 130 having one stripe-shaped window region 135 (of 3.0 μm width) is formed on the p-type GaN fourth cladding layer 125.

A first electrode 140 is formed on the n-type GaN substrate 100, and a second electrode 145 is formed on the SiO₂ layer 130 and the window region 135.

In order to emit blue light having a wavelength in the region of 405 nm from the active layer 115, the mole fraction of InN and the mole fraction of GaN of the well layers are respectively set to 0.12 and 0.88.

In the present embodiment, in order to prevent lattice defects in the layers constituted by quaternary material among the semiconductor layers noted above, the Ga composition x and the Al composition y are set such that the value of the expression (x+1.2y) is substantially equal to a constant value, and the lattice constants of the various constituting layers are set to match each other. If this constant value is set to 1±0.1, then the lattice constant matches that of GaN well, but it is more desirable to set it to 1±0.05.

The reason why the ternary InGaN is used for the well layers in the foregoing is that it is easier to control the atomic composition ratio than when using the InGaAlN material and it is possible to control the emission wavelength more precisely.

Furthermore, by appropriately selecting the material for the layers, the band gap energy of the n-type second cladding layer 110 and the p-type third cladding layer 120 can be set larger than the band gap energy of the multiple quantum well active layer 115 that includes three quantum well layers as shown in FIG. 1B. Thus, the injected carriers from the n-type second cladding layer 110 and the p-type third cladding layer 120 are confined within the active layer 115, and the carriers recombine to emit ultraviolet light. Furthermore, the refractive indices of the n-type second cladding layer 110 and the p-type third cladding layer 120 are smaller than the refractive index of the multiple quantum well active layer 115, so that the light field is confined in the lateral direction.

The current injected from the electrode 145 is confined and flows through the window region 135, so that the region within the active layer 115 below the window region 135 is strongly activated. Thus, the local mode gain within the active layer below the window region 6a becomes higher than the local mode gain within the active layer below the SiO₂ layer. Accordingly, a waveguide due to the gain waveguide brought about by the laser oscillation is formed within the semiconductor laminated structure described above.

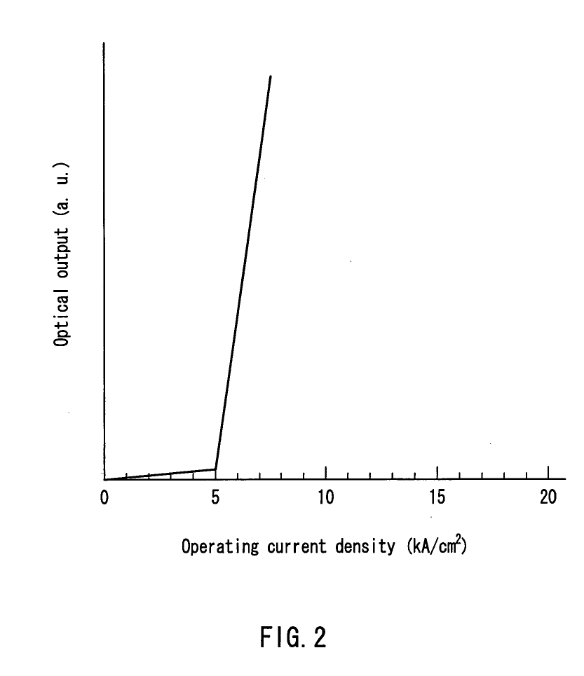

FIG. 2 shows the relationship between current and optical output characteristics of the laser diode in the present embodiment. The laser diode is driven by a pulse current of 1% duty cycle.

As FIG. 2 shows, in the laser diode of the present embodiment, the threshold current density is a sufficiently low value of 5.0 kA/cm₂, making it possible to realize a high output laser.

Method for Manufacturing the Semiconductor Light-Emitting Element

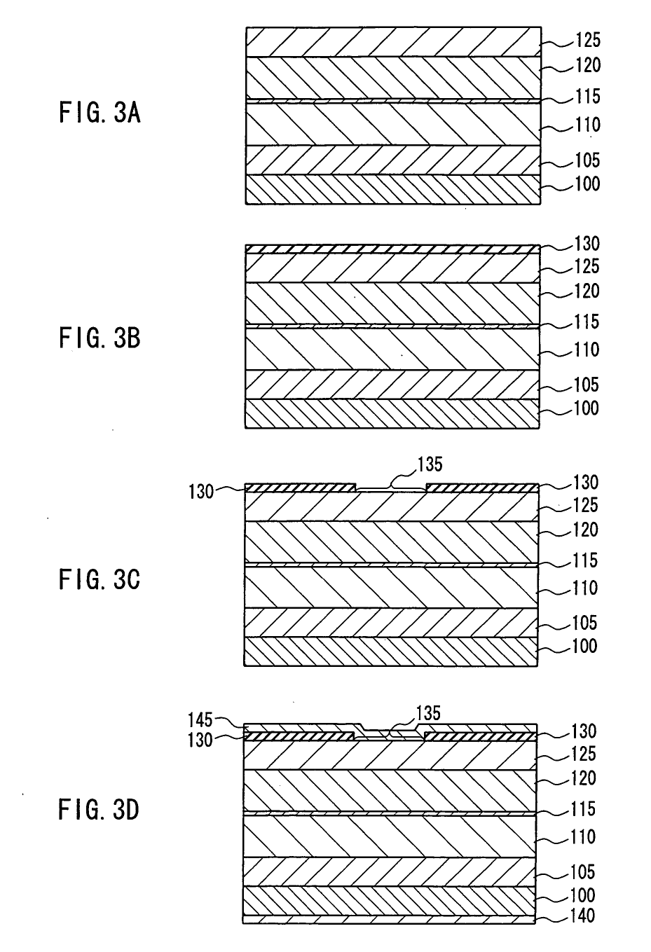

A method for manufacturing the above-described semiconductor laser according to the present embodiment is described in the following. FIGS. 3A to 3D are diagrams showing an outline of the steps for manufacturing the semiconductor laser diode according to the first embodiment. Because the structure shown in FIGS. 3A to 3D is similar to the structure shown in FIG. 1, the same reference numbers are used where possible.

First, as shown in FIG. 3A, the n-type GaN substrate 100 is provided, and the n-type GaN first cladding layer 105 is grown on top thereof The thickness of the first cladding layer 105 is typically about 0.5 μm. The n-type In_{0.05}Ga_{0.75}Al_{0.2}N second cladding layer 110 with a typical thickness of approximately 1.5 μm is formed.

Next, the multiple quantum well active layer 115 is formed by forming four of the barrier layers made of In_{0.02}Ga_{0.85}Al_{0.13}N material with a thickness of 35 angstrom (3.5 nm) and three of the quantum wells made of three layers of In_{0.12}Ga_{0.88}N material with a thickness of approximately 35 angstrom (3.5 nm) each.

After this, the third cladding layer 120 made of the p-type In_{0.05}Ga_{0.75}Al_{0.2}N material with a thickness of approximately 1.5 μm is formed, and the fourth cladding layer 125 made of the p-type GaN with a thickness of approximately 0.5 μm further is formed. Typically, the layers are formed by using metal organic chemical vapor deposition (MOCVD) or molecular beam epitaxy (MBE) or concurrent use of these processes.

Thus, as shown in FIG. 3B, the SiO₂ layer 130 is formed by chemical vapor deposition (CVD), for example, on the p-type GaN fourth cladding layer 125. Next, as shown in FIG. 3C, the window region 135 is formed by using photolithography and etching or other appropriate methods. The window region 135 may be of stripe shape.

Last, as shown in FIG. 3D, the first electrode 140 and the second electrode 145 are formed on the n-type GaN substrate 100 and the SiO₂ layer 130 respectively by vapor deposition or other appropriate methods.

### Second Embodiment

Structure of the Semiconductor Laser

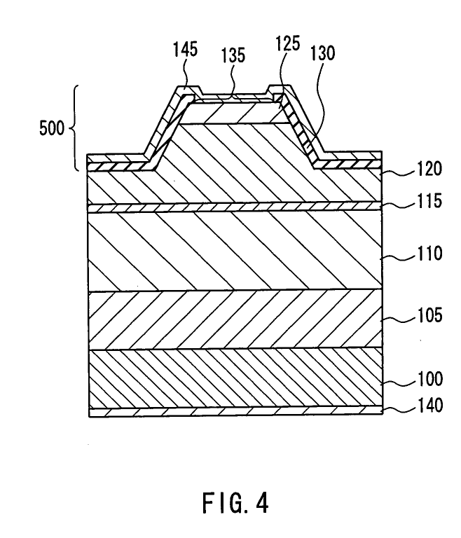

Next, a semiconductor light-emitting element according to a second embodiment of the present invention is explained with reference to FIG. 4. In FIG. 4, the same structural elements as in the first embodiment are shown with the same reference numbers. A first cladding layer 105 made of an n-type GaN with a thickness of approximately 0.5 μm, an n-type second cladding layer 110 made of In_{0.05}Ga_{0.75}Al_{0.2}N material with a thickness of approximately 1.5 μm, and a multiple quantum well active layer 115 (FIG. 1B) constituted by four barrier layers made of In_{0.02}Ga_{0.85}Al_{0.13}N material with a thickness of 35 angstrom (3.5 nm) and three quantum well layers made of In_{0.12}Ga_{0.88}N material with a thickness of approximately 35 angstrom (3.5 nm) sandwiched therebetween are formed on an n-type GaN substrate 100 in this order. Furthermore, a third p-type cladding layer 120 made of In_{0.05}Ga_{0.75}Al_{0.2}N material with a thickness of approximately 1.5 μm and a p-type GaN fourth cladding layer 125 with a thickness of approximately 0.5 μm are formed thereon, and the p-type third cladding layer 120 and the p-type fourth cladding layer 125 are partially removed to form a ridge structure 500. Furthermore, a SiO₂ layer 130 is formed to cover at least lateral faces of the ridge structure 500 and exposed portions of the remaining third cladding layer 120 outside the ridge structure 500. A stripe-shaped window region 135 with a width of approximately 2.0 μm is formed above the third cladding layer 120 and the fourth cladding layer 125 via the SiO₂ layer 130.

Furthermore, as in the first embodiment, a first electrode 140 is formed on the n-type GaN substrate 100, and a second electrode 145 is formed on the SiO₂ layer 130.

As in the first embodiment, in order to emit blue light having a wavelength in the region of 405 nm from the active layer 14, the mole fractions of InN and GaN within the wells are set to 0.12 and 0.88 respectively. Furthermore, in order to prevent lattice defects by matching the lattice constants of the constituting layers of the layers of. InGaAlN, which is a quaternary material, the Ga composition x and the Al composition y of all layers are set to satisfy the condition that the value of the expression (x+1.2y) is substantially equal to a constant value, and in order to make the lattice constants of GaN and the layers substantially equal, the value of the expression (x+1.2y) should be set to 1±0.1 and more desirably to 1±0.05.

For comparison, a laser in which the compositions of Ga and Al of the n-type In_{0.05}Ga_{0.75}Al_{0.2}N second cladding layer and the p-type In_{0.05}Ga_{0.75}Al_{0.2}N third cladding layer are set as shown in the table below, and the compositions of Al and Ga of the other constituent layers are the same as the second embodiment was manufactured, and the results of a reliability evaluation conducted at CW, 60° C., and 30 mW is shown. The lifetime of an element was defined as the time after which the value of the operating current was increased by 20% or more compared to the start of the reliability evaluation, and the determination of whether the reliability is OK or NG was made by whether or not the lifetime was 1000 hours or more. As shown in the table below, the result was that if the value of the expression (x+1.2y) is within 1±0.1, then the reliability was OK, whereas the reliability of elements not within this range was NG. It seems that if the value of the expression (x+1.2y) is less than 0.9, then the lattice constant of the In_{1-x-y}GaₓAl_{y}N layer is more than 1% larger than that of GaN, and a large compressive strain occurs in the In_{1-x-y}GaₓAl_{y}N layer, making it easier for lattice defects to occur in the In_{1-x-y}GaₓAl_{y}N layer. If the value of the expression (x+1.2y) exceeds 1.1, then the lattice constant of the InGaAlN becomes more than 1% smaller than the lattice constant of GaN, and a large tensile strain occurs in the In_{1-x-y}GaₓAl_{y}N layer, making it easier for lattice defects to occur in the In_{1-x-y}GaₓAl_{y}N layer, and resulting in the increase of the value of the operating current.

Table 1 below shows the results of the reliability evaluation for various compositions of Al and Ga of the cladding layers.

TABLE 1

| | | | | results of |
|---|---|---|---|---|
| In composition | Ga composition | Al composition | | reliability |
| (1 − x − y) | x | y | x + 1.2y | evaluation |
| 0.17 | 0.63 | 0.2 | 0.87 | NG |
| 0.14 | 0.66 | 0.2 | 0.9 | OK |
| 0.05 | 0.75 | 0.2 | 1.0 | OK |
| 0.0 | 0.5 | 0.5 | 1.1 | OK |
| 0.0 | 0.4 | 0.6 | 1.12 | NG |

As for the results of the reliability evaluation, the lifetime of an element was taken to be the time after which the value of the operating current increased by 20% or more compared to the start of the reliability evaluation, for the conditions of CW, 60° C., and 30 mW, and a lifetime of at least 1000 hours was taken to be OK whereas a lifetime of less than 1000 hours was taken to be NG. Here, CW means continuous wave.

With the present embodiment, the band gap energy of the cladding layers is maintained at a larger value than the band gap energy of the active layer, making it possible to emit ultraviolet light. Furthermore, the relationship of the refractive indices of the layers is as noted in connection with the first embodiment, and the light distribution is confined in the lateral direction.

Similar to the operation of the first embodiment, the SiO₂ layer 130 limits the region into which the current is injected to the active layer 115, and the region below the window region 135 in the active layer 115 is strongly excited.

As a result, the local mode gain within the active layer below the window region 135 becomes higher than the local mode gain within the active layer below the SiO₂ layer 130. Thus, compared to the outer side of the ridge structure 500, in conjunction with the fact that the effective refractive indices in the lateral direction inside thereof become relatively larger, a difference of the effective refractive indices (An) is obtained.

Accordingly, with the second embodiment, a semiconductor laser structure having an effective refractive index waveguide mechanism is obtained, and a low threshold current laser diode operable in fundamental transverse-mode is provided.

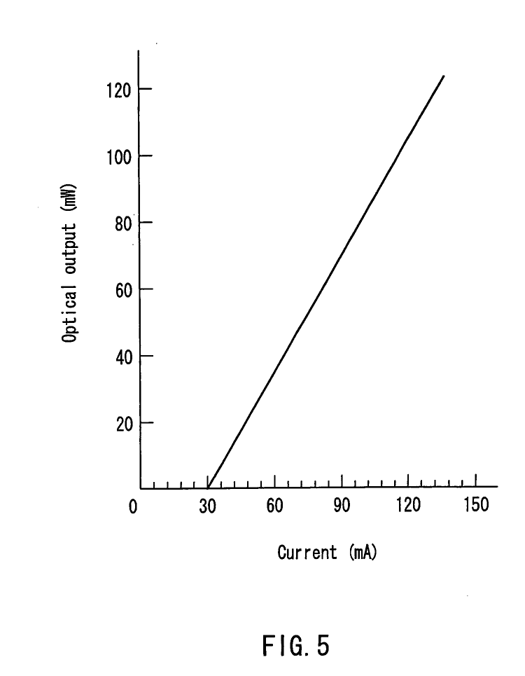

FIG. 5 is a graph of the relationship between current and optical output characteristics of the laser diode according to the second embodiment. The laser diode is driven by continuous wave current. It is apparent that the threshold current is 30 mA. Furthermore, a high output operation of 100 mW or more was possible.

Thus, with the present embodiment, not only is the leakage current reduced by using barrier layers made of InGaAlN with a large band gap as the barrier layers, but phase separation does not occur in the layers, making it possible to reduce the waveguide loss particularly in the cladding layers, prevent the occurrence of thermal saturation during high output operation, and improve temperature characteristics, and thus realize a high output laser.

Method for Manufacturing the Semiconductor Laser

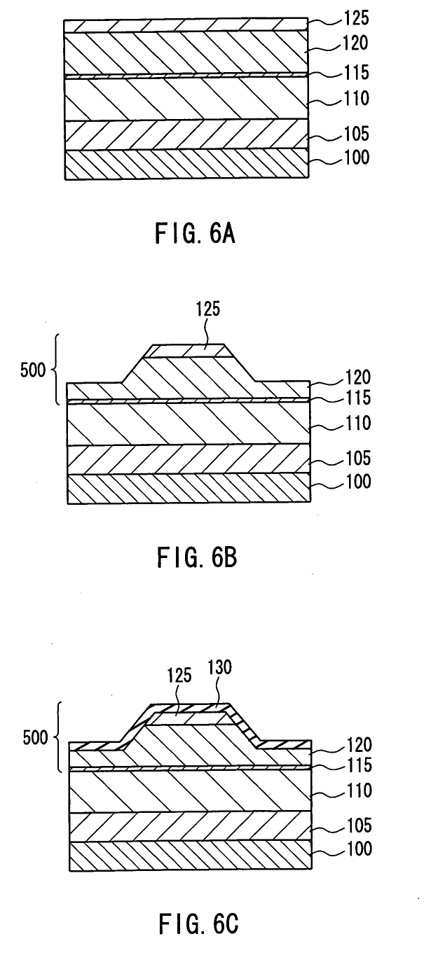

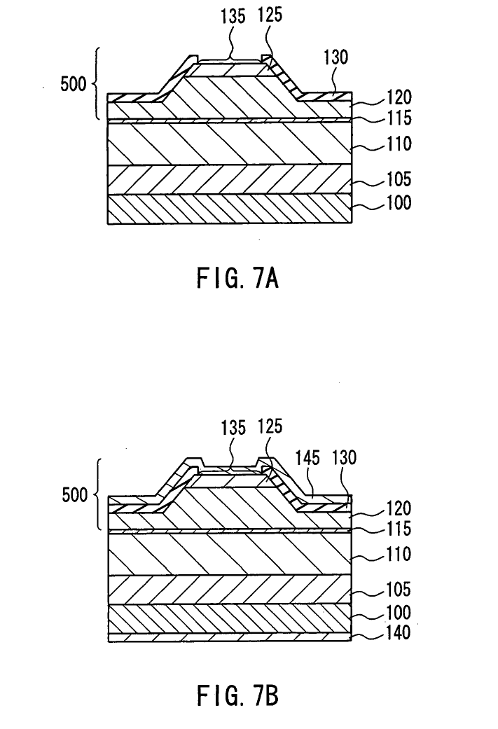

FIGS. 6A to 7B show an outline of the main steps for manufacturing the semiconductor laser according to the second embodiment. First, as shown in FIG. 6A and FIG. 6B, the first cladding layer 105, the second cladding layer 110, and a multiple quantum well active layer 115 that includes three quantum well layers (see FIG. 1B) are formed on the n-type GaN substrate 100. This method of formation is similar to that disclosed in the first embodiment. Then, the third cladding layer 120 and the fourth cladding layer 125 are formed, after which a portion thereof is removed by lithography and etching to form the ridge structure 500.

After this, as shown in FIG. 6C, FIG. 7A, and FIG. 7B, the SiO₂ layer 130 is formed typically by CVD on the third cladding layer 120 and the fourth cladding layer 125, and, as in the first embodiment, the window region 135 is formed. Then, the electrodes 140 and 145 are formed by vapor deposition or other appropriate methods.

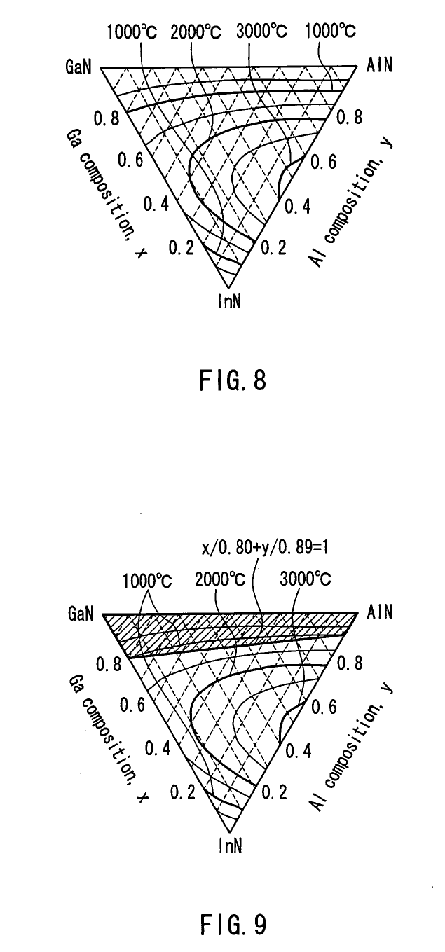

FIG. 8 shows a phase separation region of the constituent components of the InGaAlN material for various growing temperatures. In FIG. 8, the solid curves show a boundary between a region where the composition is unstable (phase separation region) and a region that is stable, for various temperatures. Regions enclosed by the straight line connecting InN and AlN (constituting one side of the phase diagram shown as a triangle) and the boundary lines given by the curves show phase separations region for InAlN, for example. It is apparent that the phase separation regions for InAlN and InGaN, which are ternary materials, are large because the lattice mismatches between InN and AlN and between InN and GaN are large. On the other hand, even if crystal growth of GaAlN is conducted at approximately 1000° C., because the lattice mismatch between AlN and GaN is small, a closed region is not formed with the straight line connecting GaN and AlN and the curves, or in other words, it is apparent that there is no phase separation.

Furthermore, as predicted from FIG. 8, when the crystal growth temperature is lower, within a range from approximately 500° C. to approximately 1000° C., for example, it is apparent that there are InGaAlN materials in which no significant phase separation of the In composition, Ga composition, and Al composition occurs.

FIG. 9 shows a hatched region from which the compositions of Ga and Al are selected in order to prevent phase separation within InGaAlN at crystal growth temperatures lower than approximately 1000° C., and it has been found that the boundary line separating the two regions can be defined approximately by the relationship represented by the following Equation 1 where x is the Ga composition and y is the Al composition:
x/0.8+y/0.89=1 (Equation 1)

Thus, in the first and second embodiments disclosed thus far, if the Ga compositions x and Al composition y in the constituting layers made of semiconductor material of the laser satisfy the relationships of equation 2 noted below, and the crystal growth of the constituting layers is performed within the temperature range from approximately 500° C. to approximately 1000° C., then it is possible to prevent the occurrence of phase separation in the constituting layers made of InGaAlN material within the semiconductor laser.
0<x+y<1 and 1<x/0.8+y/0.89 (Equation2)

As a result, it is possible to distribute the In atoms, the Ga atoms, and the Al atoms in the constituting layers in a substantially uniform manner according to the desired atomic mole fractions, and the band gap energy distribution and the refractive index distribution can be made uniform. Thus, the density of light absorption centers can be reduced, and scattering in the waveguide can be prevented, and therefore, it is possible to reduce the waveguide loss in the cladding layers and the barrier layers.

Furthermore, as shown in FIG. 9, it is apparent that in the well layers made of InGaN material, phase separation does not occur if the In composition is 0.2 or less.

On the other hand, in designing a band gap for emitting blue light, it is also necessary that the In composition of the well layers is 0.2 or less.

Thus, by using InGaN with an In composition of 0.2 or less for the well layers, phase separation does not occur, and a uniform layer growth and a favorable emission of blue light can be realized.

It should be noted that when emitting blue light, it is advantageous to use InGaN whose composition can be controlled easily for the well layers in order to increase the ease with which to control the emission wavelength rather than to use quaternary InGaAlN material.

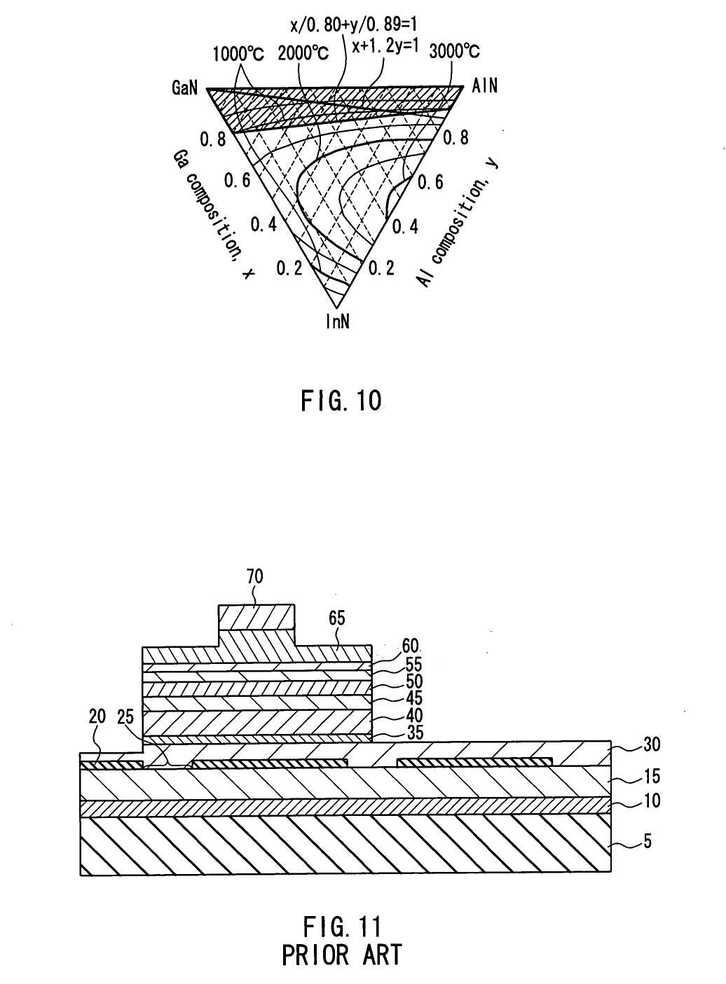

FIG. 10 shows the region from which the Ga composition x and the Al composition y are selected in order to prevent phase separation of the InGaAlN material at growth temperatures lower than approximately 1000° C. FIG. 10 shows the line x+1.2 y=1 as a bold line. The lattice constants of the InGaAlN material on this line are equal to the lattice constants of GaN. Thus, with respect to the layers constituted by InGaAlN material in the laser formed on the GaN substrate, it is possible to manufacture, on a GaN substrate, a semiconductor laser with few lattice defects and no or extremely little phase separation, by ensuring that x+1.2 y is substantially equal to 1 and that the relationships shown in Equation 2 are satisfied.

Furthermore, in the first and second embodiments, it is possible to suppress the occurrence of lattice defects in the well layers by using InGaAlN material having a lattice constant matching that of GaN for the barrier layers of the active layer.

Thus, in the above-noted embodiments, an example in which quaternary InGaAlN material is used as the cladding layers is shown, but ternary material made of AlGaN in which the difference of the lattice constant to that of GaN is relatively small also may be used.

Furthermore, the present invention is not limited to the film thickness or the composition of the layers, or the method for manufacturing, structure of the laser, and the like disclosed in the first and second embodiments and may freely be embodied in other forms without departing from the spirit thereof.

Furthermore, though not discussed in the above-noted embodiments, the present invention is not limited to the edge-emitting semiconductor lasers, but the effect thereof may also be achieved when the present invention is applied to surface emitting lasers, light-emitting diodes, or the like.

### INDUSTRIAL APPLICABILITY

The semiconductor lasers according to the present invention are particularly useful as GaN semiconductor lasers, particularly for use as high output lasers.

1. A semiconductor light-emitting element comprising:
a first cladding layer of a first conductivity type made of In_{1-x-y}GaₓAl_{y}N (0≦x, y≦1) type material;
a quantum well active layer including a barrier layer made of In_{1-x-y}GaₓAl_{y}N (0≦x, y≦1) type material and a well layer made of In₁₋ₓGaₓN (0≦x≦1) material; and
a second cladding layer of a second conductivity type made of In_{1-x-y}GaₓAl_{y}N (0≦x, y≦1) type material;
wherein the mole fractions of the constituent components of the layers are selected such that (x+1.2y) is in a range of 1±0.1.

2. The semiconductor light-emitting element according to claim 1, wherein in the first cladding layer, the barrier layer, the well layer and the second cladding layer, (x+1.2y) is in the range of 1±0.05.

3. The semiconductor light-emitting element according to claim 1, wherein a lattice mismatch of each of the first cladding layer, the barrier layer, the well layer, and the second cladding layer with GaN as a material of a substrate is at least −2.33% and at most +1.13%.

4. The semiconductor light-emitting element according to claim 1, wherein the second cladding layer has at least a ridge structure.

5. The semiconductor light-emitting element according to claim 1, wherein the relationships
0<x+y<1 and 1<x/0.8+y/0.89
are satisfied in the first cladding layer, the barrier layer, the well layer and the second cladding layer.

6. The semiconductor light-emitting element according to claim 1, wherein an electrically insulating layer serving as one stripe-shaped window region further is formed on the second cladding layer.

7. A method for manufacturing a semiconductor light-emitting element comprising:
a first cladding layer of a first conductivity type made of In_{1-x-y}GaₓAl_{y}N (0<x, y≦1) type material;
a quantum well active layer including a barrier layer made of In_{1-x-y}GaₓAl_{y}N (0≦x, y≦1) type material and a well layer made of In₁₋ₓGaₓN (0≦x≦1) material; and
a second cladding layer of a second conductivity type made of In_{1-x-y}GaₓAl_{y}N (0<x, y≦1) type material;
wherein the layers are fabricated at a crystal growth temperature of at least 500° C. and at most 1100° C., and the mole fractions of the constituent components of the layers are selected such that (x+1.2y) is in a range of 1±0.1.

8. The method for manufacturing a semiconductor light-emitting element according to claim 7, wherein in the first cladding layer, the barrier layer, the well layer and the second cladding layer, (x+1.2y) is in the range of 1±0.05.

9. The method for manufacturing a semiconductor light-emitting element according to claim 7, wherein a lattice mismatch of each of the first cladding layer, the barrier layer, the well layer, and the second cladding layer with GaN as a material of a substrate is at least −2.33% and at most +1.13%.

10. The method for manufacturing a semiconductor light-emitting element according to claim 7, wherein the relationships
0≦x+y≦1 and 1≦x/0.8+y/0.89
are satisfied in the first cladding layer, the barrier layer, the well layer and the second cladding layer.

11. The method for manufacturing a semiconductor light-emitting element according to claim 7, wherein the crystal growth temperature is at least 700° C. and at most 1100° C.

12. The method for manufacturing a semiconductor light-emitting element according to claim 7, wherein the second cladding layer has at least a ridge structure.

13. The method for manufacturing a semiconductor light-emitting element according to claim 7, wherein an electrically insulating layer serving as one stripe-shaped window region further is formed on the second cladding layer.
